(19) United States
(12) Patent Application Publication
(10) Pub. No.: US 2025/0029878 A1
(43) Pub. Date: Jan. 23, 2025

(54) METHODS FOR SEPARATING SEMICONDUCTOR DEVICES USING SINGULATION GROOVES, AND DEVICES RESULTING FROM SUCH METHODS

(71) Applicant: Micron Technology, Inc., Boise, ID (US)

(72) Inventor: Jungbae Lee, Taichung (TW)

(21) Appl. No.: 18/759,091

(22) Filed: Jun. 28, 2024

Related U.S. Application Data
(60) Provisional application No. 63/527,406, filed on Jul. 18, 2023.

(51) Int. Cl. H01L 21/78; H01L 21/02; H01L 21/304; H01L 21/3065; H01L 23/498

(52) U.S. Cl. CPC H01L 21/78; H01L 21/0226; H01L 21/304; H01L 21/3065; H01L 23/49894

(57) ABSTRACT

A method of separating a semiconductor device from another semiconductor device using singulation grooves on a substrate is provided. The method includes providing a substrate with an upper surface and a back; forming a first semiconductor device on a first location on the upper surface; forming a second semiconductor device on a second location on the upper surface, such that a gap exists between the second semiconductor device and the first semiconductor device; forming a singulation groove on the upper surface that runs through the gap between the first and second semiconductor devices; partially filling an interior of the singulation groove with a brittle dielectric filler to form an air gap in the interior of the groove, and grinding to remove excess material from the back of the substrate, such that the singulation groove cracks and a separation is formed between the first semiconductor device and the second semiconductor device.

### CROSS-REFERENCE TO RELATED APPLICATION(S)

The present application claims priority to U.S. Provisional Patent Application No. 63/527,406, filed Jul. 18, 2023, the disclosure of which is incorporated herein by reference in its entirety.

### TECHNICAL FIELD

The present disclosure generally relates to semiconductor device assemblies, and more particularly relates to methods for separating semiconductor devices using singulation grooves, and devices resulting from such methods.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified plan view of a production assembly of semiconductor devices used in a slicing process.

FIG. 2 is a simplified plan view of a production assembly of semiconductor devices used in a singulation groove process.

FIG. 3A is a simplified cross-sectional view of an example step of forming a singulation groove between a first semiconductor device and a second semiconductor device on an upper surface of a substrate.

FIG. 3B is a simplified cross-sectional view of an example step of partially filling a singulation groove with brittle dielectric material, such that an air pocket forms.

FIG. 3C is a simplified cross-sectional view of an example step of grinding to remove excess material from the back of the substrate, such that the singulation groove cracks and a separation is formed between the first semiconductor device and the second semiconductor device.

FIG. 3D is a simplified cross-sectional view of an example step of stretching a mount tape such that a separation is increased between a first semiconductor device and a second semiconductor device.

FIG. 4A is a simplified cross-sectional view of a semiconductor device having a sidewall covered in dielectric material.

FIG. 4B is a simplified detail view of a semiconductor device sidewall covered in dielectric material with a first and second cleavage site.

FIG. 4C is a simplified detail view of a semiconductor device sidewall covered in dielectric material over a layer of semiconductor material.

FIG. 5 is a schematic view showing a system that includes a semiconductor device assembly configured in accordance with an embodiment of the present technology.

FIG. 6 is a flow chart illustrating a method of making a semiconductor device assembly in accordance with an embodiment of the present technology.

### DETAILED DESCRIPTION

The electronics industry relies upon continuous innovation in the field of semiconductor packaging manufacture to meet the global need for higher-functioning technology. This demand calls for increasingly complicated assemblies of semiconductor devices, which may diverge in terms of plan area, thickness, connection methodology, etc. Finding ways to manufacture large numbers of such complicated assemblies—and at a lower cost—is a constant challenge in semiconductor manufacture.

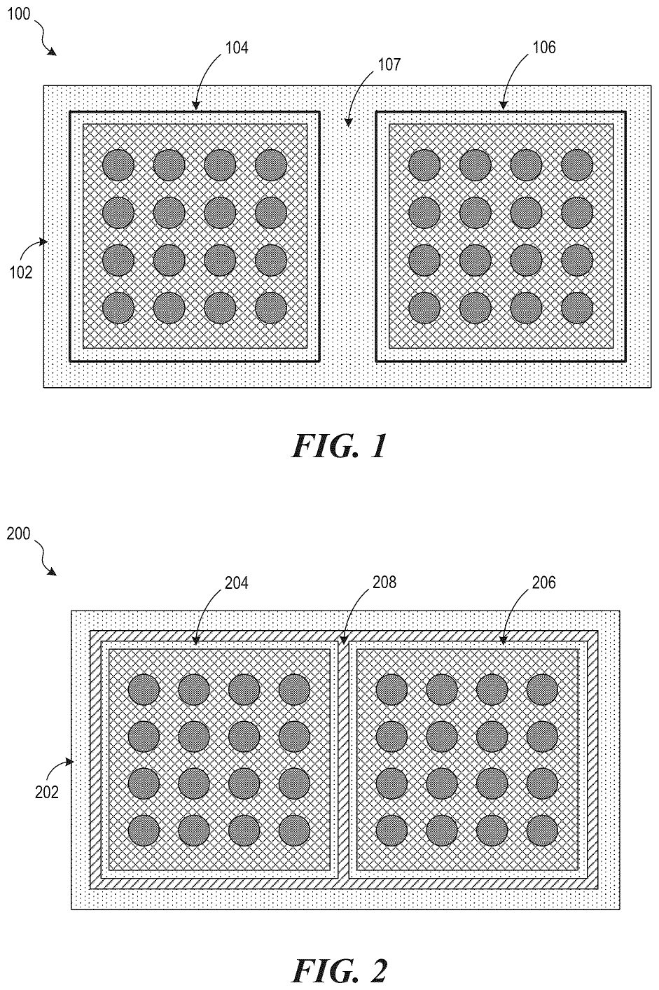

One approach manufacturers have used to meet this goal is to form semiconductor devices in a batch on top of a common substrate (e.g., a silicon wafer). This approach has the benefit of enabling manufacturers to produce the devices in bulk, but presents the question of how to separate the devices. Current solutions to this challenge include slicing the substrate to separate it into its constituent semiconductor devices. This slicing can be done with a saw or a laser. In FIG. 1, a simplified plan view of an example production assembly 100 of semiconductor devices used in a slicing process is illustrated.

The example production assembly 100 can include a substrate 102 with an upper surface, on which a first semiconductor device 104 and a second semiconductor device 106 can be formed, with a distance 107 between them allowing a saw to pass through and ultimately separate them.

Slicing the substrate 102, however, has many disadvantages. One major disadvantage of slicing the substrate 102 is that the distance 107 between the first semiconductor device 104 and the second semiconductor device 106 must be relatively large. This distance 107 can be referred to as the “saw street” or the “scribe line.” This large distance 107 is needed to avoid damaging the delicate electronics belonging to both of the semiconductor devices 104 and 106. When using a mechanical saw to separate semiconductor devices, the distance 107 between the devices 104 and 106 must be significantly large. When using a laser (i.e., “stealth dicing”), the distance 107 would be lesser than using mechanical saw but still relatively substantial. Multiplied across a 300 mm wafer, for example, this accumulated wasted space can affect total yields of the targeted semiconductor device under production.

Another problem that arises from sawing between semiconductor devices 104 and 106 is the length of time required to perform this step. For larger devices, sawing can add between ten to twenty minutes to the overall packaging process. However, as the size of the devices 104 and 106 shrinks, the number of scribe lines on the substrate 102 increases. This means that, for the very smallest devices, the process of sawing the substrate 102 to separate the first and second semiconductor devices 104 and 106 can add more than an hour to packaging.

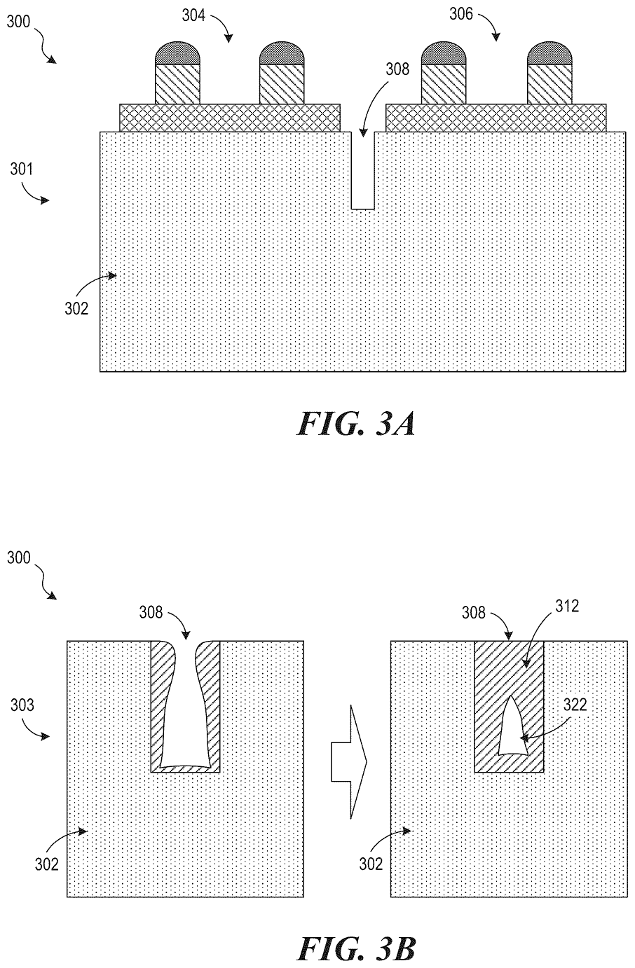

To address these drawbacks and others, various embodiments of the present disclosure provide methods for separating semiconductor devices using singulation grooves, and devices resulting from such methods. FIG. 2 provides a simplified plan view of a production assembly 200 of semiconductor devices used in a singulation groove process. The first semiconductor device 204 and second semiconductor device 206 can be formed adjacently on an upper surface of a substrate 202, such that a gap exists between them. Running through the gap and between the device 204 and 206 is a singulation groove 208. In addition to running between the devices 204 and 206, the singulation groove 208 can also be configured to create a boundary around the devices, as illustrated in FIG. 2. The groove 208 can have a shape, the shape being circular, ovoid, rectangular, or square, as in FIG. 2, or any shape. The shape of the groove 208 can match the contours of a relevant semiconductor device which the groove 208 is configured to compass.

In such a potential embodiment as the production assembly 200, the singulation groove 208 can measure up to 20 mm across. However, it should be noted, due to its method of being formed (which will be explained in the description below, and illustrated in later figures), the singulation groove 208 can be much narrower, with some embodiments having a width of 10 mm or 5 mm. Due to its narrower width, the singulation groove 208 solves the problem of wasted space presented by the scribe line 107 shown in FIG. 1. Additionally, the presence of the singulation groove 208 in the production assembly 200 removes the need for a slicing step. This reduces the overall length of time necessary to separate the semiconductor packages, and to produce completed semiconductor devices, by a process that will be explained in a later description and illustrated in later figures. Consequently, the methods disclosed herein represent a practical means of fitting a greater number of semiconductor devices onto a single production assembly, and then separating those semiconductor devices from each other more quickly, without incurring new costs in the packaging process.

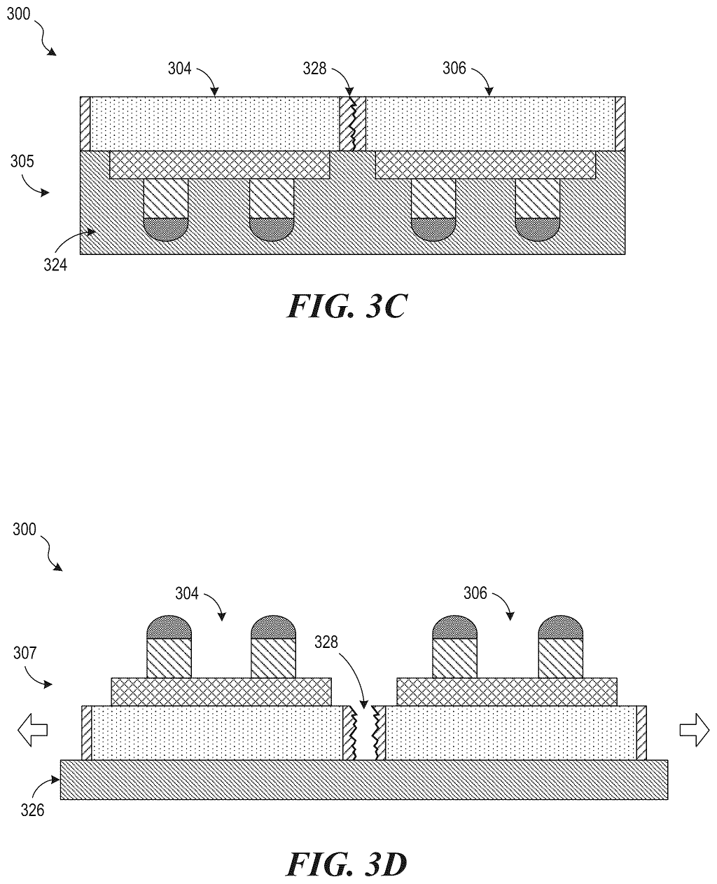

An example implementation of such a method is illustrated in FIGS. 3A-3D. These figures illustrate steps in a process 300 for separating a first semiconductor device 304 from a second semiconductor device 306, both devices located adjacently on a surface of a substrate 302.

The process 300 can include providing the substrate 302, the substrate 302 having an upper surface and a back. The substrate 302 can be a semiconductor wafer. The process 300 can include forming the first semiconductor device 304 on a first location on the upper surface and forming the second semiconductor device 306 on a second location on the upper surface. The semiconductor devices can be formed such that a gap exists between them. The process 300 can include forming a singulation groove 308 on the upper surface, such that the singulation groove runs through the gap between the first semiconductor device and the second semiconductor device.

FIG. 3A is a simplified cross-sectional view of an example step 301 in the process 300 in which a singulation groove 308 is formed between the first semiconductor device 304 and the second semiconductor device 306 on an upper surface of the substrate 302. The singulation groove 308 can run through the gap between the first semiconductor device 304 and the second semiconductor device 306. In addition to running between the devices 304 and 306, the singulation groove 308 can also be formed such that it creates a boundary around the devices. The groove 308 can have a shape, the shape being circular, ovoid, rectangular, or square, or any shape. The shape of the groove 308 can match the contours of a relevant semiconductor device which the groove 308 is configured to compass. The singulation groove 308 can have a width and a depth depending on the process that forms it. In one exemplary embodiment, the width can measure at most 20 microns, and the depth can measure at most 500 microns. The singulation groove 308 can be formed with an etching operation. The etching operation can include plasma etching, ion etching, or dry etching.

The process 300 can include partially filling an interior of the singulation groove 308 with a brittle dielectric filler 312 such that an air gap 322 forms in the interior of the groove 308. FIG. 3B is a simplified cross-sectional view of an example step 303 in the process 300 in which the singulation groove 308 is partially filled with brittle dielectric material 312 such that an air gap 322 forms. The brittle dielectric material 312 can comprise silica, porcelain, ceramic, glass, mica, plastics, a metal oxide, or any combination of the foregoing materials. Partially filling an interior of the singulation groove 308 can be done by electroplating or chemical vapor deposition. Partially filling the interior of the singulation groove can occur in less than twenty minutes, such that the air gap 322 forms within groove 208. By partially filling the groove 308, the brittle dielectric material 312 can form a bridge spanning a top of the groove 308, such that the air gap forms an air pocket 322 within the interior of the groove, such that the air pocket 322 is enclosed by dielectric material 312. The interior of the groove 308 can have a volume, and the air gap 322 can occupy over forty percent of the volume. The remaining volume can be occupied by dielectric material 312.

The process 300 can include grinding to remove excess material from the back of the substrate 302, such that the singulation groove 308 cracks and a separation 328 is formed between the first semiconductor device 304 and the second semiconductor device 306. FIG. 3C is a simplified cross-sectional view of an example step 305 in the process 300 in which excess material is removed from the back of the substrate 302 such that the singulation groove 308 cracks and a separation 328 is formed between the first semiconductor device 304 and the second semiconductor device 306. The removal of the excess material from the back of the substrate 302 can be accomplished through grinding. Additionally, in other embodiments, grinding to remove excess material from the back of the substrate 302 can include attaching a background tape 324 to an upper surface of the first semiconductor device 304 and an upper surface of the second semiconductor device 306, and inverting the substrate 302.

Additionally, in other embodiments, the method can further include rotating the substrate 302 such that the upper surface is on top, removing the background tape 324 from the first semiconductor device 304 and the second semiconductor device 306, and then mounting the back of the substrate 302 onto a mount tape 326 and stretching the mount tape 326 such that the separation 328 is increased between the first semiconductor device 304 and the second semiconductor device 306. FIG. 3D is a simplified cross-sectional view of an example step 307 in the process 300 in which a mount tape 326 is stretched such that a separation 328 is increased between a first semiconductor device 304 and a second semiconductor device 306.

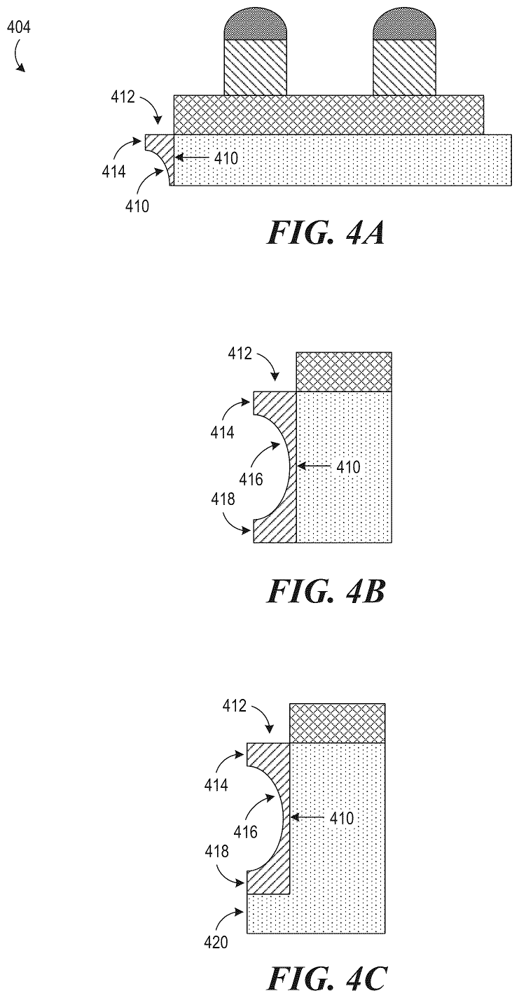

FIG. 4A is a simplified cross-sectional view of an example semiconductor device 404. The example semiconductor device can be the result of the process exemplified in the preceding Figures and description. The example semiconductor device 404 has a sidewall 410 covered in dielectric material 412. The sidewall 410 can be partially covered by the dielectric material 412, or completely covered by dielectric material 412 as illustrated in FIG. 4A. The dielectric material 412 has a profile formed by a process directed toward separating the semiconductor device 404 from an adjacent semiconductor device on a common surface of a substrate. The process can include etching a narrow superficial via across the substrate surface in a space between the devices and rapidly plating the superficial via with dielectric material such that air is trapped inside the via, as well as flipping the substrate over to expose a back side belonging to the substrate and having an excess of semiconductor material. The excess of semiconductor material can be removed through a grinding step which causes a fracture to form at the superficial via as a consequence, and results in separating the semiconductor device from the adjacent semiconductor device.

The sidewall 410 can have a top and a bottom. The dielectric material 412 can have a cleavage site 414 located at the top of the sidewall 410, as well as a tapered section 416 that angles from the cleavage site 414 inwardly toward the bottom of the sidewall 410. The dielectric material 412 can include silica, porcelain, ceramic, glass, mica, plastics, or a metal oxide. The sidewall 410 can have a height, the height measuring up to 400 microns. The dielectric material 412 can have a width, the width measuring up to 50 microns. The semiconductor device 404 can have a width and a length, the width or length measuring at least 0.5 microns, and up to twenty microns.

Additionally, in other embodiments, the dielectric material 412 can include a second cleavage site. FIG. 4B is a simplified detail view of a semiconductor device sidewall 410 covered in dielectric material 412 with a first cleavage site 414 and second cleavage site 418 below the tapered section 416. In alternative embodiments, the tapered section 416 of dielectric material can, after angling in toward the sidewall 410, then angle back out toward the second cleavage site 418, as illustrated in FIG. 4C. Alternatively, the tapered section 416 can angle in toward the sidewall 410 all the way from the first cleavage site 414 to the second cleavage site 418. The second cleavage site 418 can have a bottom that is flush with the bottom of the sidewall 410, where the second cleavage 418 site extends out from the tapered section 416 and has a width equal in measurement to a width of the first cleavage site 414, as illustrated in FIG. 4B. Alternatively, the width of the second cleavage site 418 can be less than the width of the first cleavage site 414, or greater than the width of the first cleavage site 414.

Additionally, in other embodiments, a layer of semiconductor material can exist below the second cleavage site 418. FIG. 4C is a simplified detail view of a semiconductor device sidewall 410 covered in dielectric material 412 over a layer of semiconductor material 420. The layer of semiconductor material 420 can have an edge that juts out from below the second cleavage site 418, or the layer of semiconductor material 420 can be completely covered by the second cleavage site 418, as illustrated in FIG. 4C. Alternatively, the second cleavage site 418 can extend out further from the sidewall 410 than the layer of semiconductor material, such that the second cleavage site 418 forms an overhang over the layer of semiconductor material 420.

Although in the foregoing example embodiment semiconductor device assemblies have been illustrated and described as including a single semiconductor device, in other embodiments assemblies can be provided with additional semiconductor devices. For example, the single semiconductor devices illustrated in FIGS. 1-4C, could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 2-10 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

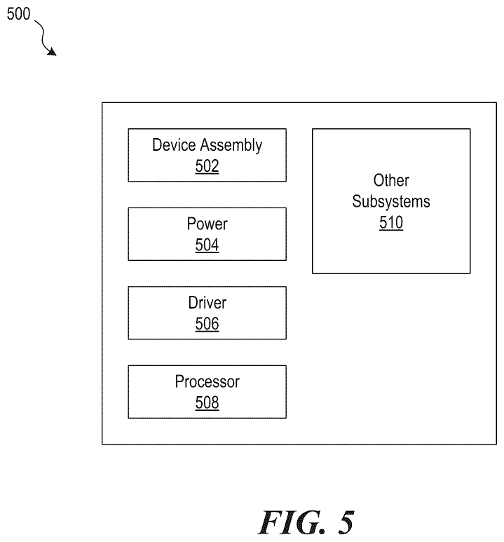

Any one of the semiconductor devices and semiconductor device assemblies described above with reference to FIGS. 2-4C can be incorporated into any of a myriad of larger and/or more complex systems, a representative example of which is system 500 shown schematically in FIG. 5. The system 500 can include a semiconductor device assembly (e.g., or a discrete semiconductor device) 502, a power source 504, a driver 506, a processor 508, and/or other subsystems or components 510. The semiconductor device assembly 502 can include features generally similar to those of the semiconductor devices described above with reference to FIGS. 2-4C. The resulting system 500 can perform any of a wide variety of functions, such as memory storage, data processing, and/or other suitable functions. Accordingly, representative system 500 can include, without limitation, hand-held devices (e.g., mobile phones, tablets, digital readers, and digital audio players), computers, vehicles, appliances, and other products. Components of the system 500 may be housed in a single unit or distributed over multiple, interconnected units (e.g., through a communications network). The components of the system 500 can also include remote devices and any of a wide variety of computer readable media.

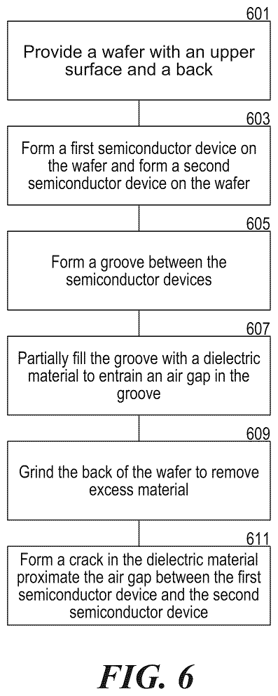

FIG. 6 is a flow chart illustrating a method of making a semiconductor device assembly. The method includes providing a wafer with an upper surface and a back (box 601). The method further includes forming a first semiconductor device on a first location on the upper surface and forming a second semiconductor device on a second location on the upper surface, such that a gap exists between the second semiconductor device and the first semiconductor device (box 603). The method further includes forming a singulation groove on the upper surface, such that the singulation groove runs through the gap between the first semiconductor device and the second semiconductor device (box 605). The method further includes partially filling an interior of the singulation groove with a brittle dielectric filler such that an air gap is entrained in the interior of the groove (box 607). The method further includes grinding the back of the wafer to remove excess material (box 609). The method further includes forming a crack in the dielectric material proximate the air gap between the first semiconductor device and the second semiconductor device (box 611).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method of singulating a first semiconductor device and a second semiconductor device from a wafer, the method comprising:
forming a first semiconductor device on a first location on an upper surface of the wafer;
forming a second semiconductor device on a second location on the upper surface, such that a distance exists between the second semiconductor device and the first semiconductor device;
forming a singulation groove on the upper surface in the distance between the first semiconductor device and the second semiconductor device;
partially filling an interior of the singulation groove with a dielectric material to entrain an air gap in the interior of the groove; and
grinding to remove excess material from a back surface of the wafer opposite the upper surface; and
forming a crack in the dielectric material proximate the air gap between the first semiconductor device and the second semiconductor device.

2. The method of claim 1, wherein the singulation groove has a width and a depth, the width measuring less than or equal to 10 microns, and the depth measuring less than or equal to 200 microns.

3. The method of claim 1, wherein the singulation groove is formed with an etching operation, including plasma etching, ion etching, or dry etching.

4. The method of claim 1, wherein the dielectric material comprises silica, porcelain, ceramic, glass, mica, plastics, or a metal oxide.

5. The method of claim 1, wherein partially filling the interior of the singulation groove comprises electroplating or chemical vapor deposition of the dielectric material.

6. The method of claim 1, wherein partially filling the interior of the singulation groove is performed in less than fifteen minutes.

7. The method of claim 1, wherein the dielectric material forms a bridge spanning a top of the groove, such that the air gap is entrained below the bridge.

8. The method of claim 1, wherein the interior of the singulation groove has a volume, and the air gap occupies at least fifty percent of the volume.

9. The method from claim 1, wherein the method further comprises:
rotating the wafer such that the upper surface is on top;
removing a background tape from the first semiconductor device and the second semiconductor device;
mounting the back of the wafer onto a mount tape; and
stretching the mount tape such that the distance is increased between the first semiconductor device and the second semiconductor device.

10. A semiconductor device having a sidewall covered in a dielectric material with a profile including a cleavage region, wherein the cleavage region represents a portion of the profile, and wherein the profile is formed by partially filling an interior of a singulation groove in a wafer between the semiconductor device and an adjacent device with a dielectric material such that an air gap is entrained in the interior of the singulation groove, thinning the wafer from an inactive bottom surface of the semiconductor device, and forming a crack in the dielectric material proximate the air gap.

11. The semiconductor device of claim 10, wherein the interior of the singulation groove is partially filled by an electroplating process or by chemical vapor deposition.

12. The semiconductor device of claim 10, wherein the dielectric material comprises silica, porcelain, ceramic, glass, mica, plastics, or a metal oxide.

13. A semiconductor device, comprising:
a substrate sidewall extending from a top of the semiconductor device to a bottom of the semiconductor device, the sidewall covered in dielectric material, the dielectric material including:
a substantially vertical cleavage site at a top of the sidewall; and
a tapered uncleaved section angling in from the cleavage site toward a bottom of the sidewall.

14. The semiconductor device of claim 13, wherein the dielectric material comprises silica, porcelain, ceramic, glass, mica, plastics, or a metal oxide.

15. The semiconductor device of claim 13, wherein the sidewall has a height measuring less than or equal to 200 microns.

16. The semiconductor device of claim 13, wherein the dielectric material has a width measuring less than or equal to 10 microns.

17. The semiconductor device of claim 13, wherein the device has a width and a length, the width and length measuring less than or equal to four mm.

18. The semiconductor device of claim 13, the dielectric material comprising a second cleavage site below the tapered uncleaved section.

19. The semiconductor device of claim 18, wherein the second cleavage site has a bottom that is flush with the bottom of the sidewall, wherein the second cleavage site extends away from the sidewall and has a width equal in measurement to a width of the cleavage site at the top of the sidewall.

20. The semiconductor device of claim 18, further comprising a layer of semiconductor material below the second cleavage site.
